(19) United States
(12) Patent Application Publication
(10) Pub. No.: US 2024/0090136 A1
(43) Pub. Date: Mar. 14, 2024

(54) PRINTED CIRCUIT BOARD OBFUSCATION SYSTEMS AND METHODS

(71) Applicant: UNIVERSITY OF FLORIDA RESEARCH FOUNDATION, INCORPORATED, Gainesville, FL (US)

(72) Inventors: Navid ASADI-ZANJANI, Gainesville, FL (US); John TRUE, Gainesville, FL (US); Chengjie XI, Gainesville, FL (US); Aslam KHAN, Gainesville, FL (US)

(21) Appl. No.: 18/463,988

(22) Filed: Sep. 8, 2023

Related U.S. Application Data
(60) Provisional application No. 63/375,280, filed on Sep. 12, 2022.

(51) Int. Cl. H05K 3/00

(52) U.S. Cl. CPC H05K 3/0005

(57) ABSTRACT

Various embodiments of the present disclosure provide a framework for obfuscation of a printed circuit board (PCB). In one example, an embodiment provides for generating a plurality of connections interconnecting a plurality of components of the PCB using additive manufacturing, permuting, using a micro electro-mechanical systems (MEMS) device, a first set of connections interconnecting a first component with a second component in the PCB, integrating the MEMS device into the PCB such that the MEMS device covers a second set of connections from an x-ray probe, probing the PCB using x-ray simulation, and iteratively adjusting the permutation of the first set of connections and the integration of the MEMS device using a result of the x-ray simulation to reduce the detectability of the first and second connections based on the result of the x-ray simulation.

### CROSS REFERENCE TO RELATED APPLICATIONS

This application claims priority to U.S. Appl. No. 63/375,280 filed Sep. 12, 2022, the contents of which are incorporated herein in its entirety by reference.

### TECHNICAL FIELD

The present application relates to the technical field of Printed Circuit Boards (PCBs) design. In particular, the disclosure relates to security associated with Printed Circuit Boards (PCB s).

### BACKGROUND

Semiconductor manufacturing has been outsourced to various geographical regions due to globalization. Further, an entity may handle only certain aspects of design and/or fabrication while other stages may be outsourced to others. As a result, the totality of the fabrication process may not be easily or fully secured. The complex multistep fabrication of micro-scale integrated circuits (ICs) and the tedious assembly of macro-scale Printed Circuit Boards (PCBs) may be vulnerable to malicious attacks from design to final delivery. PCBs may provide the functional connections of Integrated Circuits (ICs), sensors, power supplies, etc., of many electronic systems for consumers, corporations, and governments. The feature sizes of PCB signal traces in 2D and vias in 3D are an order of magnitude larger than IC devices, and may be thereby more vulnerable to non-destructive attacks such as X-ray or probing.

### SUMMARY

In general, embodiments of the present invention provide methods, apparatus, systems, computing devices, computing entities, and/or the like for providing a multi-layered framework for security of integrated circuits. The details of some embodiments of the subject matter described in this specification are set forth in the accompanying drawings and the description below. Other features, aspects, and advantages of the subject matter will become apparent from the description, the drawings, and the claims.

In an embodiment, a method for netlist obfuscation of a printed circuit board (PCB) is provided. The method may provide for generating a plurality of connections interconnecting a plurality of components of the PCB using additive manufacturing, permuting, using a micro electro-mechanical systems (MEMS) device, a first set of connections interconnecting a first component with a second component in the PCB, integrating the MEMS device into the PCB such that the MEMS device covers a second set of connections from an x-ray probe, probing the PCB using x-ray simulation, and iteratively adjusting the permutation of the first set of connections and the integration of the MEMS device using a result of the x-ray simulation to reduce the detectability of the first and second connections based on the result of the x-ray simulation.

In an embodiment, the additive manufacturing includes three-dimensional printing of the plurality of connections in the PCB. In an embodiment, the method provides for creating a design manufacturing file in response to a result of the x-ray simulation being satisfactory, wherein the design manufacturing file includes instructions on the permutation of the first set of connections and the integration of the MEMS device, and the design manufacturing file configured to be used in netlist obfuscation of another printed circuit board.

In an embodiment, the method provides for supplemental obfuscation of the PCB in response to the result of the x-ray simulation not being satisfactory. In an embodiment, the supplemental obfuscating includes adding dummy traces and dummy vias to the PCB. In an embodiment, the supplemental obfuscating includes rearranging a plurality of surface mount devices in the PCB.

In an embodiment, a method for netlist obfuscation of a printed circuit board (PCB) is provided. The method may provide for generating a plurality of connections interconnecting a plurality of components of the PCB using additive manufacturing, permuting, using a micro electro-mechanical systems (MEMS) device, a set of connections interconnecting a first component with a second component in the PCB, and integrating the MEMS device into the PCB such that an Integrated Circuit (IC) in the PCB covers the MEMS device from an x-ray probe.

In an embodiment, the x-ray probe when having a power higher than a threshold power is destructive to the IC. In an embodiment, the x-ray probe, when having a power lower than the threshold power, is incapable of successfully scanning the MEMS device or determining the permutation of the set of connections. In an embodiment, the method includes probing the PCB using an x-ray simulation, and iteratively adjusting the integration of the MEMS device using a result of the x-ray simulation to reduce the detectability of the set of connections based on the result of the x-ray simulation.

In an embodiment, a method for obfuscating connections between a first Integrated Circuit (IC) and a second IC of a printed circuit board (PCB) is provided. The method may provide inputting a PCB design file determining countermeasures for obfuscating the connections between the first IC and second IC, performing an X-ray countermeasure simulation to determine a level of obfuscation of the connections between the first and the second IC, receiving a set of selections for countermeasure settings, generating X-ray projections from collection types and geometries commensurate with the received set of selections for countermeasure settings, extracting information on the connections between the first and second ICs by reconstructing X-ray data, and determining whether the countermeasures are sufficient for obfuscation.

In an embodiment, the set of selections for countermeasure settings comprises a level of difficulty of reverse engineering of the PCB design, a specific connection of the connections between the first and second ICs for high priority obfuscation, an upper limit of cost or overhead for obfuscation, a desired cost or time for reverse engineering of the connections, or an X-ray tool specification. In an embodiment, the method provides converting the PCB design file to a manufacturing file when the countermeasures are sufficient for obfuscation.

In an embodiment, when the countermeasures are sufficient for obfuscation, the method provides selecting a set of the connections between the first IC and the second IC that are visible to the X-ray. In an embodiment, the method provides reconfiguring the PCB design file to obfuscate the set of the connections that are visible to the X-ray. In an embodiment, the reconfiguring the PCB design file comprises rearranging a surface-mount device (SMD) to absorb X-ray energy. In an embodiment, the reconfiguring the PCB design file comprises adding dummy traces to the connections between the first IC and the second IC. In an embodiment, the reconfiguring of the PCB design file comprises permuting, using a micro electro-mechanical systems (MEMS) device, the connections between the first IC and the second IC. In an embodiment, the MEMS device obfuscates the connections between the first IC and the second IC.

In an embodiment, the method provides iteratively repeating, inputting the PCB design file, performing the X-ray countermeasure simulation to determine the level of obfuscation of the connections between the first and the second IC, receiving the set of selections for countermeasure settings, generating X-ray projections from collection types and geometries commensurate with the received set of selections for countermeasure settings, extracting information on the connections between the first and second ICs by reconstructing X-ray data, and determining whether countermeasures are sufficient for obfuscation, until the countermeasures are sufficient for obfuscation.

### BRIEF DESCRIPTION OF THE DRAWINGS

Reference will now be made to the accompanying drawings, which are not necessarily drawn to scale, and wherein:

FIG. 1 illustrates an example graph of various obfuscation methods;

FIG. 2 illustrates an example process for using a MEMS device to permute interconnections of a PCB, according to one or more embodiments herein;

FIG. 3 illustrates an example process for using and/or evaluating a MEMS device to permute interconnections of a PCB, according to one or more embodiments herein;

FIG. 4 illustrates an example method for circuit obfuscation, according to one or more embodiments herein;

FIG. 5 illustrates an example result of X-ray scanning, according to one or more embodiments herein;

FIG. 6A illustrates an example method for PCB obfuscation, according to one or more embodiments herein;

FIG. 6B illustrates an example method for PCB obfuscation, according to one or more embodiments herein;

FIG. 7A illustrates an example method for PCB obfuscation, according to one or more embodiments herein;

FIG. 7B illustrates an example method for PCB obfuscation, according to one or more embodiments herein;

FIG. 7C illustrates an example method for PCB obfuscation, according to one or more embodiments herein; and

FIG. 8 illustrates a schematic of a computing entity that may be used in conjunction with one or more embodiments of the present disclosure.

### DETAILED DESCRIPTION

The present disclosure more fully describes various embodiments with reference to the accompanying drawings. It should be understood that some, but not all, embodiments are shown and described herein. Indeed, the embodiments may take many different forms, and accordingly, this disclosure should not be construed as limited to the embodiments set forth herein. Rather, these embodiments are provided so that this disclosure will satisfy applicable legal requirements. Like numbers refer to like elements throughout.

Various embodiments of the present disclosure provide methods and systems to prevent or reduce the effectiveness of PCB attacks or probing. Active and/or passive countermeasures may be successfully developed for IC devices. In some instances, it may be challenging for PCB devices to be wholly secured from all attacks. Passive countermeasures for X-ray attacks using high atomic number (high-z) materials to block and scatter X-rays may be effective. However, use of of active and passive countermeasures tailored for PCBs are desirable. Various embodiments provide passive obfuscation of a PCB's critical connections between components, such as ICs, from non-destructive attacks. Various embodiments further incorporate active countermeasures.

In various embodiments, a PCB electronic design automation (EDA) tool which combines features of micro electro-mechanical systems (MEMS), simulation of X-ray, and 3D PCB Manufacturing to iteratively optimize PCB design to thwart reverse engineering and probing attacks are provided.

In various embodiments herein, a method for generating multiple connections interconnecting various components of the PCB is provided. The method may use additive manufacturing, for example three-dimensional printing. The method may use a MEMS device to permute a set of the connections interconnecting two or more components of the PCB. In various embodiments herein, the method may integrate the MEMS device into the PCB such that the MEMS device covers another set of connections from an x-ray probe.

### I. Example PCB Attacks

Due to the importance of securing the operation of critical electronics for healthcare, transportation, communications, etc. there is great interest in protecting PCBs from tampering or reverse engineering. PCBs may provide the functional connections of integrated circuits (ICs), sensors, power supplies, etc., for electronic systems. Critical electronic equipment such as those found in military, healthcare, and transportation applications rely upon the functionality of PCBs to perform various computing, sensing, and actuating operations. Due to the larger scale features of a PCB, when compared to an IC, the PCB's circuitry has become greatly vulnerable to unauthorized operations such as cloning, overproduction, tampering, Intellectual Property (IP) theft, etc. Some hardware assurance methods that have been used are focused on the IC scale, while hardware attacks upon PCBs can be performed without the need for high energy metrology equipment necessary for IC attacks.

Anti-reverse engineering and tampering methods for PCBs have been proposed successfully based upon programmable permutations of connected components using field programmable gate arrays (FPGAs). Prior protection methods have incorporated passive and active countermeasures, for example, high-z materials to increase X-ray noise and FPGA devices capable of circuit tamper detection respectively.

Programmable connectivity methods based on programmable permutations of connected components using FPGAs may still be susceptible to non-destructive X-ray computed tomography reverse engineering to obtain the obfuscated connections. For this reason, X-ray blocking materials may be used to prevent reverse engineering of PCB circuitry between layers. These obfuscation and permutation techniques may demonstrate effective PCB protection; however, X-ray blocking materials and FPGA logic locking are not always compatible with current PCB fabrication and design methods. In order to provide low-cost obfuscation for PCB designs, there is a need for a reproducible mass-manufactured hardware obfuscation component that is not vulnerable itself to tampering. In various embodiments herein, a MEMS is used as a reproducible mass-manufactured hardware that provides connectivity obfuscation in a PCB.

### II. Example Obfuscation, Mems Devices, and Additive Manufacturing

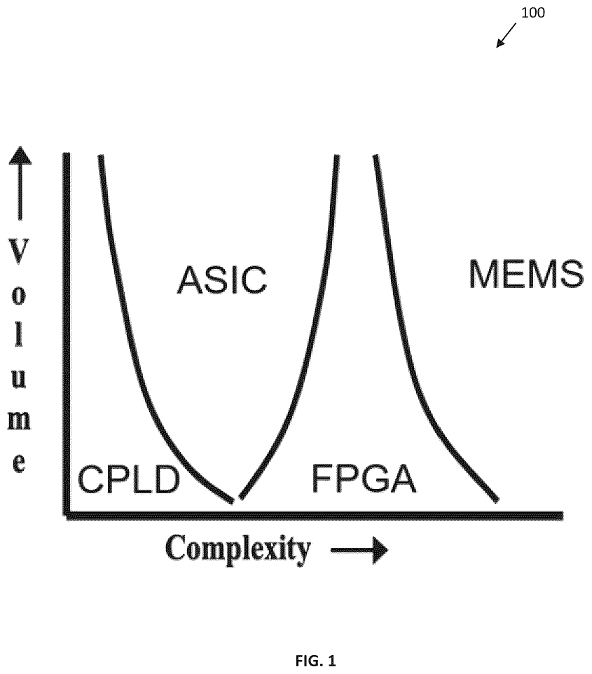

FIG. 1 illustrates a graph 100 indicating manufacturing volume and complexity of design when using various device categories that may be used for PCB obfuscation. Complex Programmable Logic Device (CPLD) or Application Specific Integrated Circuit (ASIC) devices may be used for defense mechanism by providing PCB obfuscation, as they are more applicable to higher volume designs and low complexity, but they may not be able to provide active protection. Using an FPGA to provide a defense mechanism may be suitable for low volume applications where complexity is high and the high cost per unit is not design prohibitive. However, it is desirable to provide active security protection for PCBs with high complexity and volume. According to various embodiments herein, MEMS-based active and passive protection offers the high volume and low cost of ASIC devices with the security advantages of active FPGA defense mechanisms.

### A. Example PCB Obfuscation Techniques

The attack landscape for PCB obfuscation may include any of brute-force, surface trace probing, memory compromise, re-installation, middle-layer probing, and/or IC reverse engineering. Although some active and passive anti-tampering mechanisms for ICs may be known, it is desirable to provide defense mechanisms for PCBs.

Taking PCB countermeasures and examples of board-level Trojans into account, a taxonomy for establishing benchmarks for security is presented below and used in various embodiments herein.

Active Tampering Protection: an active protection technique may be used to prevent attacks after manufacturing such as physical in-field tampering of PCBs. When utilizing customized PCB designed circuitry, it may be demonstrated that active protection techniques require low-overhead, and/or low resource cost to implement. Active protection techniques may make some of the components that characterize the circuitry's unique electrical properties trace-resistance. This method is capable of detecting different types of physical tampering in PCB which are common after manufacturing. This defense mechanism provides protection from tampering attacks by placing the components internally, where it is difficult to probe. This solution, however, may be vulnerable to temperature and aging attacks along with probing attacks that have design knowledge, such as the designs that may be collected using an X-ray computed tomography (CT).

Physical Unclonable Functions (PUFs): PUFs may be utilized in PCB designs, where natural manufacturing variations create naturally random bit strings for encryption. PUF defense mechanisms may be derived from silicon manufactured devices and/or commercially available designs. Since PUFs are developed to be based on silicon manufacturing, applying common PUFs to PCBs may be challenging. In an example, a PUF design that incorporates randomness from variation in the PCB substrate from manufacturing may be used to generate unique and stable IDs for each PCB. In this example, the randomness may be generated from a single copper trace. This trace connects multiple, e.g. three, differential frequency notch filter structures in series. The individual traces are each designed to reject specific but alternative frequencies. This example demonstrates the ability for PUFs to be successfully implemented into PCB designs with low overhead cost.

Joint Test Action Group (JTAG) Verification of Components: although chip level authentication using PUFs may be developed and implemented, countermeasures for some PCB designs may not be available. The countermeasures that require large design space or overhead may limit integration. In an example, algorithmic techniques confirming the authenticity of connected components such as ICs may be used to provide authentication for PCBs to mitigate attacks such as counterfeiting, cloning, and in-field malicious modifications. In various examples, this algorithmic methodology may require less than one percent of hardware overhead at the manufacturing phase.

### B. Example Additively Manufactured Electronics

In various approaches that have been used, there may not have been widespread additive manufacturing or 3D-printed electronics market growth such as the market adoption seen by the metal or plastic 3D-printed industry. Various embodiments use insulating and conducting materials. This may provide using the 3D-printed electronics for complex materials designs. Additionally, in accordance with various embodiments, using additive manufactured electronics such as PCBs may provide for manufacturing PCB substrate and connecting components in various geometries that may not be possible with traditional PCB manufacturing.

Nano manufacturing may offer an environment capable of 3D-printing substrates combined with automated pick-and-place component integration. This process may enable flexibility in manufacturing of various PCB designs that may provide for preventing attack vectors from malicious manufacturers in the supply chain. Nano manufacturing may utilize a direct printing of printed circuit boards having electromagnetically-shielded tracks and/or components for protecting traces from tampering. These insulation-jacketed tracks and/or components with metallic shielding sleeves can be utilized to reduce crosstalk and/or prevent tampering.

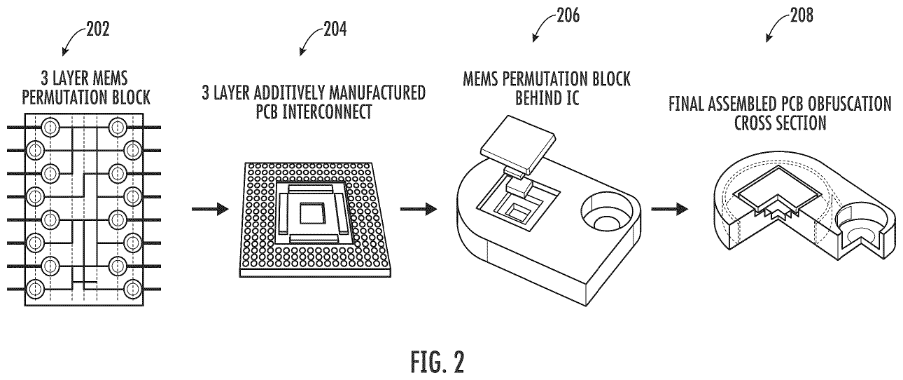

FIG. 2 is a schematic diagram illustrating various steps in providing PCB obfuscation using MEMS. In various embodiments, using 3D-printed PCB manufacturing may provide defense mechanisms that are less vulnerable to tampering attacks such as probing or non-destructive reverse engineering through X-ray computed tomography (CT) data collection. Referring to FIG. 2, according to an example embodiment, a MEMS permutation block is designed and generated, as for example shown in 202. The permutation block may, for example, be a three-layer MEMS permutation block.

An additively manufactured PCB interconnect is shown in 204 as may be used in various embodiments herein. In various embodiments, a method for generating multiple connections interconnecting multiple components of the PCB is provided. The method may use additive manufacturing, for example three-dimensional printing. The PCB interconnect 204 may, for example, be a three-layer interconnect. The MEMS permutation block may be integrated or placed behind an IC in the PCB, as for example shown in 206. In various embodiment herein, a cross section of an assembled PCB obfuscation may be similar to the example shown in 208.

In various embodiments herein, a method is provided that may use a MEMS device to permute a set of the connections interconnecting two or more components of the PCB. In various embodiments, a MEMS Permutation Block combined with additively manufactured PCB interconnect may enable obfuscation of MEMS permutation block behind an IC by increasing X-ray inspection resource requirements for inspection. This may further provide protection against an X-ray probing into the MEMS block, for example, because the X-ray probe would have the IC as additional barrier before reaching the MEMS block. This may enhance the security of the PCB since increased X-ray inspection resource maybe more difficult to attain and it may be destructive to the IC and/or the PCB, hence preventing a successful X-ray scan. In various embodiments, a lower power for the X-ray inspection that may not be destructive to the IC, will not successfully scan the MEMS to determine the permutation.

In various embodiments herein, the method may integrate the MEMS device into the PCB such that the MEMS device covers another set of connections from an x-ray probe. X-ray scans with power higher than a threshold may be destructive to the other set of connections, and X-ray scans with power lower than the threshold may not successfully scan the MEMS to determine the permutation.

### C. Example Micro Electro-Mechanical Systems (MEMS)

In various embodiments herein, MEMS are integrated micro-scale devices or systems combining electrical and mechanical components. These devices may be fabricated to be compatible with the high-volume semiconductor manufacturing methods. MEMS can vary in scale from micro-meters to milli-meters. Using mechanical and electrical properties, MEMS can be used as any of micro sensors, actuators, electronic interconnections, and/or controllers which can manipulate macro-sized systems, such as the connections, layout, and/or other components/properties in a PCB, according to various embodiments herein.

MEMS devices may be mass manufactured and packaged and may possess unique process variations which can be used for identification and/or physical unclonable function generation as used in various embodiments herein. These Physical Unclonable Functions (PUFs) combined with other properties of MEMS can be used actively or passively protect a PCB from circuit tampering, probing, reverse engineering, and/or component removal according to various embodiments herein.

While IC devices may be fixed in silicon, MEMS are capable of mechanical deformability which enables tunability and reconfigurability. For Radio Frequency (RF) based MEMS, signal inputs can be redirected, via actuation, on output lines. This may be done, for example, by means of a star-like central multiple switching unit, or by relying on ohmic RF-MEMS switches, according to various embodiments herein.

### III. Example PCB Obfuscation

According to various embodiments herein, MEMS may be combined with additive manufacturing (3D) of PCB interconnects to provide multi-layer permutation and obfuscation for high volume PCB designs. According to various embodiments, using MEMS for providing PCB obfuscation may lower cost.

### A. Example Vulnerable Minimum Feature Size of PCB Circuitry

PCB designs may follow the Institute of Printed Circuits (IPC) standards for determining signal and power trace size requirements. These may be 100-150 microns in scale to carry the necessary frequencies and power without causing cross-talk or thermal meltdown. X-ray computed tomography may be capable of characterizing PCB circuitry at macro scale with high power sources, and the IC components on the nano-scale with lower powered nano-focus sources. However, it may be challenging to characterize densely populated PCB assemblies (PCBAs) which consist of the PCB substrate, ICs, and passive components according to various embodiments herein.

PCB designs may be vulnerable to non-destructive reverse engineering if the circuitry's smallest feature sizes are within the capability of the X-ray CT system's resolvable spatial resolution. MEMS devices may be on the size scale of IC components, and can be implemented into a PCB design to enable obfuscation through permutation of circuitry for high volume designs according to various embodiments herein.

### B. Example MEMS Permutation Block

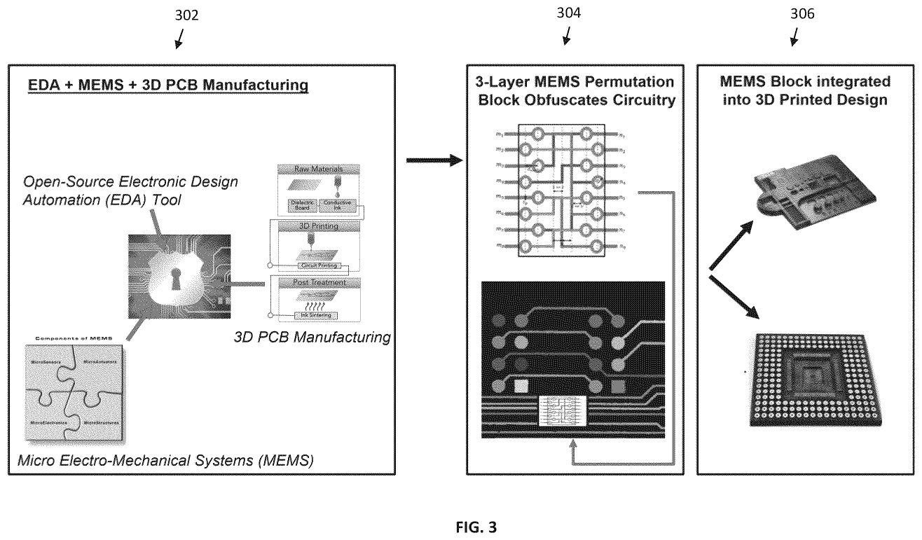

FIG. 3 illustrates a process according to one or more embodiments in the present disclosure for using MEMS in PCB manufacturing. In various embodiments an Electronic Design Automation (EDA) tool and/or software may be used to design PCB circuitry with MEMS permutation blocks which obfuscate connections between components, as for example shown in 302. In various embodiments herein, additive and/or 3D PCB Manufacturing may be used to develop complex geometries for integrating MEMS permutation blocks into the PCB design.

In various embodiments herein, the MEMS device may take in multiple signal traces through the soldered pins and lead frame acting as a bridge for example as shown in FIG. 3. In various embodiments herein, these bridged connections, which at the macro-scale may be vulnerable to X-ray CT, become microscale connections inside the MEMS package, which are more difficult to characterize. The smaller scale of the circuitry may require higher energy X-ray sources or the removal of components, rendering the process destructive.

In various embodiments herein, the circuitry may be altered to a smaller micro-scale permutated connection using the MEMS device. According to one or more embodiments, packaging material of the MEMS device may include X-ray blocking materials, which may improve the various defense mechanisms to obfuscate critical connections of the PCB. Various embodiments herein may provide PCB designers a method to iteratively obfuscate critical connections using PCB electronic design automation (EDA) software. In various embodiments herein, a PCB EDA tool may combine the small features of MEMS, simulation of X-ray, and 3D PCB Manufacturing to iteratively optimize PCB design to thwart reverse engineering and probing attacks, as for example shown in 302. In various embodiments herein, EDA may be used to study the impact of each measure (e.g., using MEMS, burying MEMS under an IC, using X-ray blocking material) and adjust the process or adjust each of the measures accordingly to achieve the desired level of obfuscation and/or cost.

In various embodiments herein, MEMS-based obfuscation may provide increased protection against middle-layer probing via X-ray micro-CT by preventing accurate reconstruction of internal features and/or internal circuitry, as for example shown in 304. Various embodiments herein may prevent surface trace probing by burying the MEMS permutation block behind multiple components, as for example shown in 306, requiring destructive removal. In various embodiments, this burying of the permutation block is accomplished through additive manufacture of PCB interconnects and will limit re-installation attacks where the permutation block is removed and reused.

In various embodiments herein, due to the micro-scaled features of the MEMS-based obfuscation, accurate X-ray inspection may require the use of higher energy sources and collection times to sample the obfuscated MEMS circuitry. Additive manufacturing techniques as used in various embodiments herein may enable the complex geometries necessary to further complicate the non-destructive analysis. PCB components may be arranged on the front or back side of a PCB. In various embodiments, using 3D PCB manufacturing may provide for orientation of components in three dimensions.

### C. Example PCB Signal Trace Obfuscation X-ray Simulation

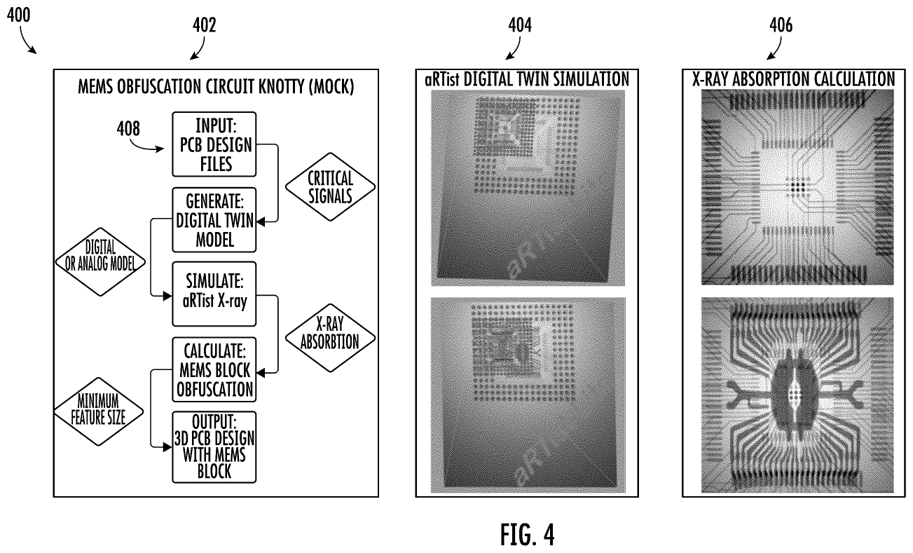

FIG. 4 illustrates a process 400 for X-ray PCB Design Simulation according to one or more embodiments of the present disclosure. Various embodiments herein provide for X-ray PCB Design Simulation to enhance the obfuscation of the PCB. For example, accurate X-ray simulation may be used for optimizing and/or nondestructive volumetric analysis such as qualifying, predicting, interpreting, training, etc., on X-ray systems. Software tools such as aRTist may offers analytical modelling of the X-ray interactions during the inspection process. In various embodiments herein, as for example shown in 402, using X-ray simulation may enable a user to input a Computer-aided design (CAD) object for performing simulations upon it. In various embodiments, simulation software may be used to determine the X-ray interactions between the MEMS permutation block, PCB substrate, and the effect of changing X-ray geometry or scan parameters without the need for costly X-ray empirical testing.

In various embodiments herein, the effectiveness of micro-scale features and X-ray blocking MEMS packaging materials upon the requirements for X-ray sampling may be determined through X-ray simulation of a digital twin model of a PCB, as for example shown in 404.

In an example, the model of the PCB may be generated from the PCB design files, for example at block 408. In various embodiments, X-ray simulation may be used to demonstrate that the combination of increasingly small MEMS features encapsulated with X-ray blocking packaging material may require the use of Nano-CT or Synchrotron energies to enable non-destructive reverse engineering, which may drastically increase the expense to reverse engineer. In various embodiments herein, the X-ray simulation is used to iteratively determine the necessary level of obfuscation to prevent PCB design reverse engineering with X-ray tools where the added component increases the complexity of the X-ray image and causes saturation in regions of high density.

In various embodiments herein, digital twin models of the PCB interconnect and IC designs may be integrated into an X-ray simulation software, such as aRTist. This Monte Carlo-based photon ray tracing tool can be used to determine the penetration depth and spatial resolution obtainable with various X-ray settings. These parameters may create the upper bounds for iteratively determining the necessary 3D printed interconnect design which will obfuscate X-rays from characterizing the sandwiched MEMS bridge, in between the PCB substrate and the ICs it protects.

Various embodiments herein provide a MEMS Obfuscation Circuit Knotty (MOCK) process 402, as for example shown in FIG. 4. In various embodiments herein, the MOCK process 402 uses MEMS inherent micro-scale circuit connections to passively obfuscate the critical connections between components on a PCB. The input PCB design files may be used to generate a digital twin model, or X-ray of physical PCB can result in an analog model, according to various embodiments herein. This twin model, whether analog or digital based, is loaded into the X-ray simulation software to determine the X-ray absorption and spatial resolution requirements. An example of X-ray absorption calculation outputs are shown in 406. These X-ray parameters may be used to determine the optimal MEMS block obfuscation geometry, packaging composition, and minimum feature size of the circuitry to prevent X-ray characterization. Various embodiments herein provide an output including a 3D PCB design file that can be virtually sliced or used otherwise for 3D PCB manufacturing.

### D. Example PCB EDA Software Tool

In various embodiments herein, the PCB design tools may be used for designers and manufactures to successfully fabricate functional embedded devices. In various embodiments herein EDAs may be used for circuit design, simulation and PCB design. The EDA circuit simulator can calculate the system of equations for a circuit under test from its design files. In various embodiments herein, these tools may be used to increase PCB design efficiencies and reduce errors. Various embodiments herein provide PCB signal integrity which may provide for better security and operation of the device and to provide signal integrity after fabrication. Monte Carlo-based simulation methods can enable designers to simulate their design and its vulnerabilities before the final design for fabrication. Various embodiments herein provide for algorithmic methods to analyze PCB designs and improve the design based on the analyses results. In various embodiments herein, the algorithmic design, e.g., using Monte Carlo simulations, provide for an optimal global analysis compared to randomly searching for parameters combinations which may provide a sub-optimum result for securing PCB designs.

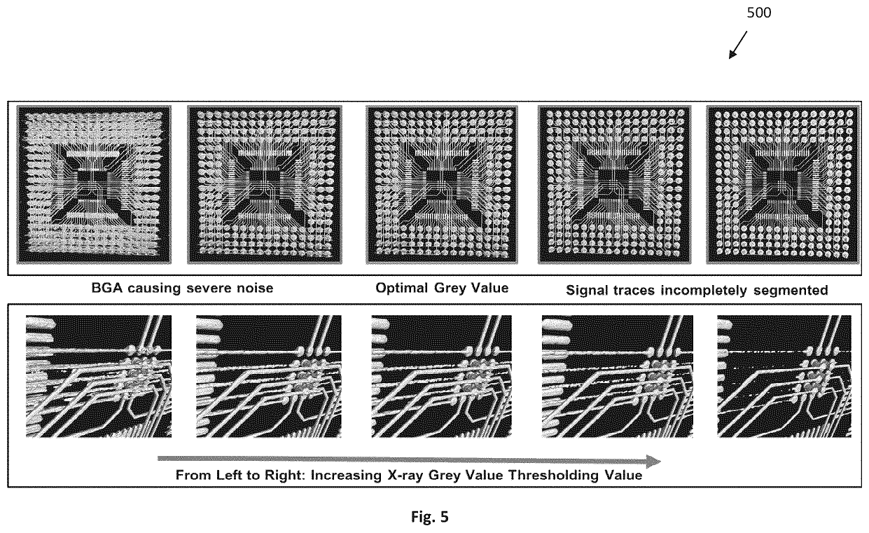

FIG. 5 illustrates various results 500 for X-ray scanning according to one or more embodiments herein. In various embodiments herein, the disclosed workflow for securing PCB designs with MEMS, EDA, X-ray simulation, and 3D PCB manufacturing demonstrates an effective solution to the growing vulnerabilities for PCB non-destructive attacks. In various embodiments, PCB EDA tools such as thermal, electromagnetic, and environmental simulations may be used in the dynamics of PCBs interactions.

Various embodiments herein provide access to real-time X-ray simulation showing how the PCB design may be vulnerable to certain inspection techniques. The workflow according to various embodiments herein incorporates data such as data 500 shown in FIG. 5 to determine whether the PCB designs can increase or decrease the difficulty of being characterized non-destructively using an X-ray scan. The top layer shown in FIG. 5 illustrates a PCB 3-layer interconnect with various X-ray iso value segmented volumes. According to one or more embodiments, the middle volume demonstrates optimal Grey value selection, while the others may indicate suffering from BGA noise or signal traces being incompletely segmented, therefore losing information. The bottom layer of FIG. 5 shows increasing iso values; 22212, 22627, 22764, 23178, 24420 respectively from left to right according to various embodiments herein. Using studies, as for example shown in FIGS. 3-5, various embodiments herein may determine whether the level of obfuscation provides the needed security for a PCB.

### E. Example Iterative Process to Obfuscate the PCB Design

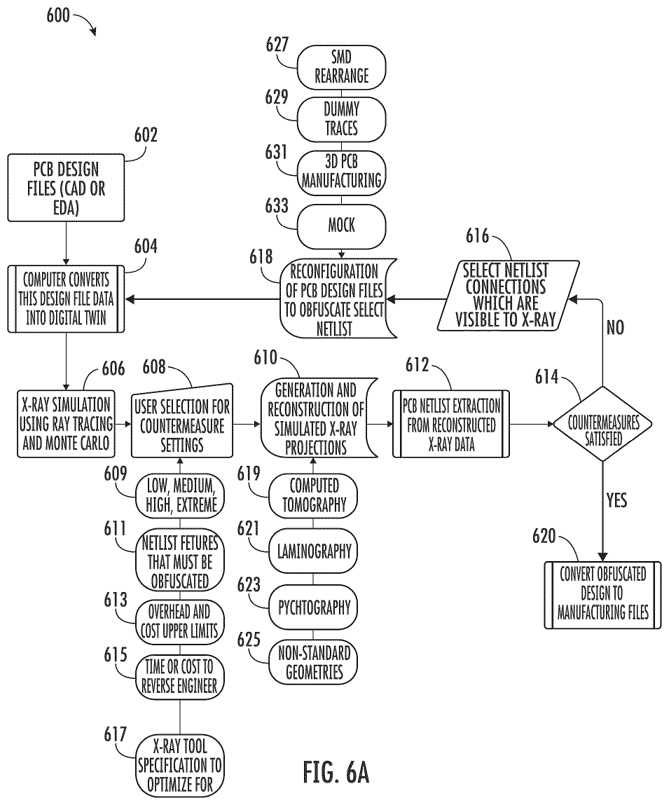

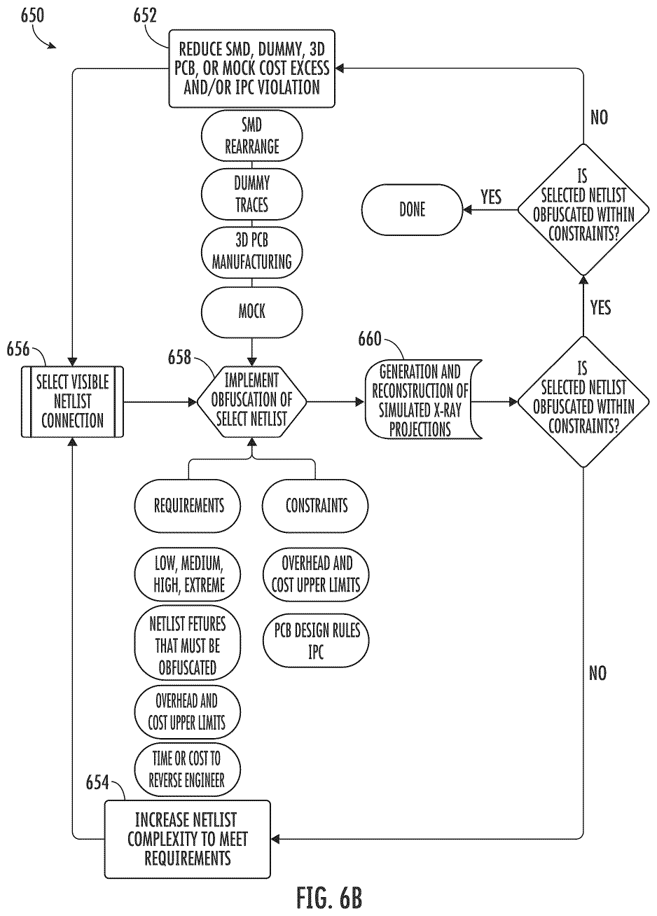

FIG. 6A is a flowchart illustrating a method 600 for obfuscating the PCB design using X-ray simulation according to one or more embodiments of the present disclosure. In various embodiments the method 600 may input PCB design files and/or user countermeasure settings and perform an iterative process to obfuscate the PCB design using X-ray simulation. The method 600 may illustrate the overall functionality of the system, where PCB design files are loaded into a computer at step 602 according to various embodiments herein. In various embodiments herein, at step 604 the computer may perform a conversion of the design file into a digital twin model representing the original design file. In various embodiments this may be done through the use of EDA software which utilizes a computer-aided manufacturing (CAM) processer to generate manufacturing files. These manufacturing files are the instructions for creating a physical PCB using manufacturing equipment. In various embodiments herein, the instructions can be further converted into a digital model using automated or manual methods which interpret the instructions to generate a digital model akin to the physical. In various embodiments, the PCB design files may be converted to any format usable by the method 600.

In various embodiments herein, at step 606 the method 600 may perform X-ray simulation using Ray tracing and Monte Carlo simulation. In various embodiments herein, at step 608, a user will select a series of PCB design countermeasure requirements and/or constraints that may be used to iteratively determine the PCB design that would satisfy the requirements and/or constraints. First, at step 609, in accordance with various embodiments herein, the low, medium, high, or extreme setting may be used to set a level of the difficulty of reverse engineering of the PCB design. Second, at step 611, in accordance with various embodiments herein, specific netlist connections can be selected for critical obfuscation, which may prioritize the obfuscation of these netlist connections relative to the others within the circuit. Third, at step 613, in accordance with various embodiments herein, the upper bound for cost and complexity may be determined by inputting the maximum overhead in area or volume which can be added to the PCB to increase difficulty, while the cost upper limits are determined by implementation of more complex manufacturing techniques such as additive manufacturing or incorporation of MEMS circuitry such as “MOCK”. Fourth, at step 615, in accordance with various embodiments herein, the desired minimum time and cost to reverse engineer a PCB design can be input as a requirement. Fifth, at step 617, in accordance with various embodiments herein, a specific X-ray tool or grouping of tools can be selected to “defend” against, where the X-ray capabilities (X-ray voltage, sample size, variable cost of X-ray source, etc.) of these systems are used as the requirements to determine optimal countermeasure design. In various embodiments, the steps 609, 611, 613, 615, or 617 described above may be performed at any order, for example at the order described above.

In various embodiments herein, at step 610, the digital model of the PCB may be used to generate X-ray projections from various collection types and geometries associated with the “countermeasure difficulty” selected. For example, extreme countermeasure settings may incorporate all possible types of X-ray projections, collections and/or settings achievable with known equipment, while low countermeasure settings will simulate X-ray projections, collections and/or settings using commonly accessible equipment. In various embodiments, the X-ray projections is generated from collection types and geometries commensurate with the received set of selections for countermeasure settings. For example, method 600 may use any of computed tomography at step 619, laminography at step 621, pychtography at step 623, and/or non-saturated geometries at step 625.

In various embodiments herein, once the simulated data has been generated and reconstructed, at step 612, the PCB netlist features are segmented and extracted from the simulated reconstructed data. In accordance with various embodiments herein, segmentation may be performed using thresholding, manual, or automated methods such as machine learning or artificial intelligence. In various embodiments, the extracted netlist may by separated into obfuscated and visible connections.

In various embodiments herein, the method 600 may use a decision block 614 to determine if selected countermeasures have been satisfied for the original PCB design, or if the design will need to be increased in complexity. In various embodiments, the method 600 may select netlist connections that are visible to the X-ray at step 616, if the selected countermeasure has not been satisfied. In accordance with various embodiments herein, if the method 600 determines that the selected countermeasures are not satisfied, it will reconfigure the PCB design to obfuscate a selected netlist at step 618. For example, at step 627 the remaining netlist features which are visible will have their netlist complexity increased through the rearrangement of any of PCB design files and/or surface-mount device (SMD) components to absorb X-ray energy and increase difficulty for X-ray scanning.

In accordance with various embodiments herein, if SMD rearrangement is not adequate, adding dummy traces at step 629 and/or 3D PCB manufacturing at step 631 may be implemented to increase difficulty. In various embodiments herein, dummy traces can be placed nearby in 3D space to cause shadowing, partial volume effect, or beam hardening to obfuscate adjacent traces. In various embodiments herein, dummy vias and/or pads can be placed nearby in 3D space instead and/or as well as dummy traces.

If all of these implementations still do not satisfy the given countermeasure settings, in various embodiments, the MOCK system can be implemented at step 633 where a MEMS device is used to obfuscate the traces of critical connections in combination with the use of 3D manufacturing. In various embodiments herein, after appropriate reconfiguration, the newly obfuscated PCB design may be used as the start of the beginning of the iterative process. In various embodiments herein, when the countermeasures are satisfied, at step 620, the obfuscated design is converted to digital form, simulated, and its netlist is extracted to confirm that the countermeasure settings have been satisfied.

In various embodiments, any and/or all of the steps of the method 600 may be performed.

FIG. 6B illustrates a method 650 according to one or more embodiments of the present disclosure. Method 650 demonstrates the iterative process of checking for satisfiability of requirements and constraints given the countermeasure settings. In accordance with various embodiments herein, the method 650 may be the decision process for obfuscation of a single netlist component given constraints and requirements from a user selection. In various embodiments herein, if constraints are breached, the obfuscation complexity may need be reduced at step 652, while if the requirements are not met, the obfuscation complexity may need to be increased at step 654. In various embodiments herein, the process illustrated by method 650 is performed iteratively until a PCB design can be exported that meets the satisfiability.

In various embodiments, at step 656 the method 650 selects the netlist connections that are visible to the X-ray and/or are not obfuscated. At step 658, the method 650 implements the obfuscation of the selected netlist. In the implementation, the method 650 considers various requirements such as level of obfuscation (e.g. low, medium, high, extreme), netlist features that must be obfuscated, specific X-ray tool to optimize for, and/or time or cost to reverse engineer after the obfuscation. The method 650 also considers carious constrains for the implementation, such as the overhead and cost upper limits, and/or PCB design rules IPC.

In various embodiments, at step 660, the method 650 generates and reconstructs the simulated X-ray projections and proceeds to revaluate to determine whether the selected netlist obfuscation is within the requirements and continues the iterative process.

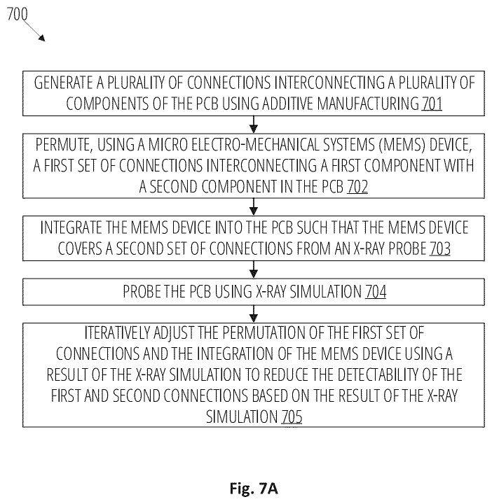

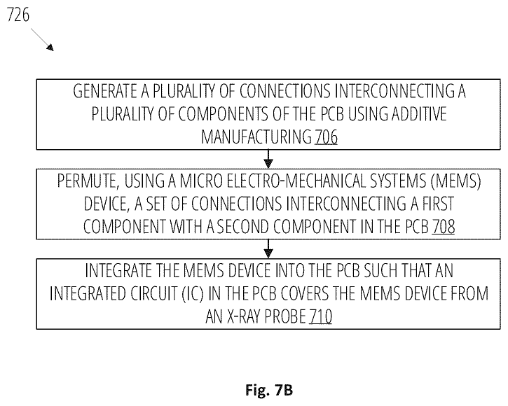

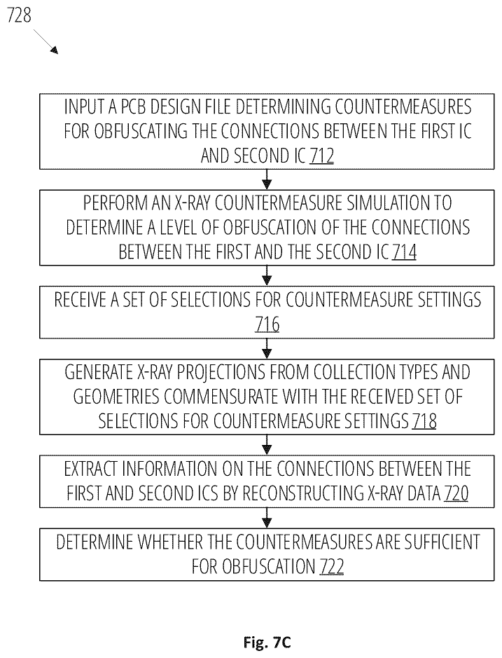

FIG. 7A illustrates a method 700 according to one or more embodiments of the present disclosure. In step 701, method 700 generates a plurality of connections interconnecting a plurality of components of the PCB using additive manufacturing. In step 702, method 700 permutes, using a micro electro-mechanical systems (MEMS) device, a first set of connections interconnecting a first component with a second component in the PCB. In step 703, method 700 integrates the MEMS device into the PCB such that the MEMS device covers a second set of connections from an x-ray probe. In step 704, method 700 probes the PCB using x-ray simulation. In step 705, method 700 iteratively adjusting the permutation of the first set of connections and the integration of the MEMS device using a result of the x-ray simulation to reduce the detectability of the first and second connections based on the result of the x-ray simulation.

In various embodiments, the additive manufacturing includes three-dimensional printing of the plurality of connections in the PCB. In an embodiment, the method provides for creating a design manufacturing file in response to a result of the x-ray simulation being satisfactory, wherein the design manufacturing file includes instructions on the permutation of the first set of connections and the integration of the MEMS device, and the design manufacturing file configured to be used in netlist obfuscation of another printed circuit board.

In various embodiments, the method provides for supplemental obfuscation of the PCB in response to the result of the x-ray simulation not being satisfactory. In an embodiment, the supplemental obfuscating includes adding dummy traces and dummy vias to the PCB. In an embodiment, the supplemental obfuscating includes rearranging a plurality of surface mount devices in the PCB.

FIG. 7B illustrates a method 726 according to one or more embodiments of the present disclosure. In step 706, method 726 generates a plurality of connections interconnecting a plurality of components of the PCB using additive manufacturing. In step 708, method 726 permutes, using a micro electro-mechanical systems (MEMS) device, a set of connections interconnecting a first component with a second component in the PCB. In step 710, method 726 integrates the MEMS device into the PCB such that an Integrated Circuit (IC) in the PCB covers the MEMS device from an x-ray probe.

In various embodiments, the x-ray probe when having a power higher than a threshold power is destructive to the IC. In an embodiment, the x-ray probe, when having a power lower than the threshold power, is incapable of successfully scanning the MEMS device or determining the permutation of the set of connections. In an embodiment, the method includes probing the PCB using an x-ray simulation, and iteratively adjusting the integration of the MEMS device using a result of the x-ray simulation to reduce the detectability of the set of connections based on the result of the x-ray simulation.

FIG. 7C illustrates a method 726 according to one or more embodiments of the present disclosure. In step 712, method 728 inputs a PCB design file determining countermeasures for obfuscating the connections between the first IC and second IC. In step 714, method 728 performs an X-ray countermeasure simulation to determine a level of obfuscation of the connections between the first and the second IC. In step 716, method 728 receives a set of selections for countermeasure settings. In step 718, method 728 generates X-ray projections from collection types and geometries commensurate with the received set of selections for countermeasure settings. In step 720, method 728 extracts information on the connections between the first and second ICs by reconstructing X-ray data. In step 722, method 728 determines whether the countermeasures are sufficient for obfuscation.

In various embodiments, the set of selections for countermeasure settings comprises a level of difficulty of reverse engineering of the PCB design, a specific connection of the connections between the first and second ICs for high priority obfuscation, an upper limit of cost or overhead for obfuscation, a desired cost or time for reverse engineering of the connections, or an X-ray tool specification. In an embodiment, the method provides converting the PCB design file to a manufacturing file when the countermeasures are sufficient for obfuscation.

In various embodiments, when the countermeasures are sufficient for obfuscation, the method provides selecting a set of the connections between the first IC and the second IC that are visible to the X-ray. In an embodiment, the method provides reconfiguring the PCB design file to obfuscate the set of the connections that are visible to the X-ray. In an embodiment, the reconfiguring the PCB design file comprises rearranging a surface-mount device (SMD) to absorb X-ray energy. In an embodiment, the reconfiguring the PCB design file comprises adding dummy traces to the connections between the first IC and the second IC. In an embodiment, the reconfiguring of the PCB design file comprises permuting, using a micro electro-mechanical systems (MEMS) device, the connections between the first IC and the second IC. In an embodiment, the MEMS device obfuscates the connections between the first IC and the second IC.

In various embodiments, the method provides iteratively repeating, inputting the PCB design file, performing the X-ray countermeasure simulation to determine the level of obfuscation of the connections between the first and the second IC, receiving the set of selections for countermeasure settings, generating X-ray projections from collection types and geometries commensurate with the received set of selections for countermeasure settings, extracting information on the connections between the first and second ICs by reconstructing X-ray data, and determining whether countermeasures are sufficient for obfuscation, until the countermeasures are sufficient for obfuscation.

As described with respect to various embodiments of the present disclosure, semiconductor manufacturing and subsequently the PCB supply chain is globalized where multiple parties may be responsible for a device's design, fabrication, testing, and deployment. PCB manufacturing technology is desired to be developed at the same rate as IC wafer level manufacturing. IC devices may have active protection methods, and devices at this scale benefit from passive protection as it may be difficult to analyze smaller structures nondestructively. In various embodiments herein, countermeasures may be used for PCBs and CAD-based design tools may be used for ICs, but IC countermeasures alone cannot protect an entire PCB from non-destructive analysis and tampering. These nondestructive attacks may be dangerous as they can be used to inform minimally destructive attacks or for reverse engineering.

While IC devices themselves may benefit from tamper resistant designs, it is desirable to have adequate EDA software tools available to PCB designers for protecting critical connections after fabrication, as described in various embodiments herein.

In various embodiments herein, an automated workflow is provided that can protect the circuit connections between critical IC packages in PCB. This workflow can also be applied to secure any interconnect device from malicious non-destructive reverse engineering.

Various embodiments herein use a combination of active and/or passive protection into a low-cost MEMS device, offering PCB designers the ability to select which IC connections should be protected. Various designs of IC packages can be incorporated into a 3D printed interconnect (as for example shown in FIG. 5) where the custom MEMS device (as for example shown in FIG. 2) provides the bridge between the IC designs for critical high-volume PCB designs.

According to various embodiments herein, the MEMS device may obfuscate connections between multiple integrated circuits, increasing the difficulty of successful non-destructive X-ray design derivation. In various embodiments, advanced iterations could incorporate passive X-ray absorbing materials such as tantalum in the packaging, in addition to adding active internal mechanisms to adaptively reconfigure the circuitry, further obfuscating the design.

PCB designs without countermeasures may be vulnerable to third parties' reverse engineering when compared to designs with passive and/or active protection according to various embodiments herein.

### Example Technical Implementation of Various Embodiments

Embodiments of the present disclosure may be implemented in various ways, including as computer program products that comprise articles of manufacture. Such computer program products may include one or more software components including, for example, software objects, methods, data structures, and/or the like. A software component may be coded in any of a variety of programming languages. An illustrative programming language may be a lower-level programming language such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established or fixed) or dynamic (e.g., created or modified at the time of execution).

A computer program product may include a non-transitory computer-readable storage medium, storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid state drive (SSD), solid state card (SSC), solid state module (SSM)), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may also be implemented as methods, apparatus, systems, computing devices, computing entities, and/or the like. As such, embodiments of the present disclosure may take the form of a data structure, apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises a combination of computer program products and hardware performing certain steps or operations.

Embodiments of the present disclosure are described with reference to example operations, steps, processes, blocks, and/or the like. Thus, it should be understood that each operation, step, process, block, and/or the like may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some example embodiments, retrieval, loading, and/or execution may be performed in parallel such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

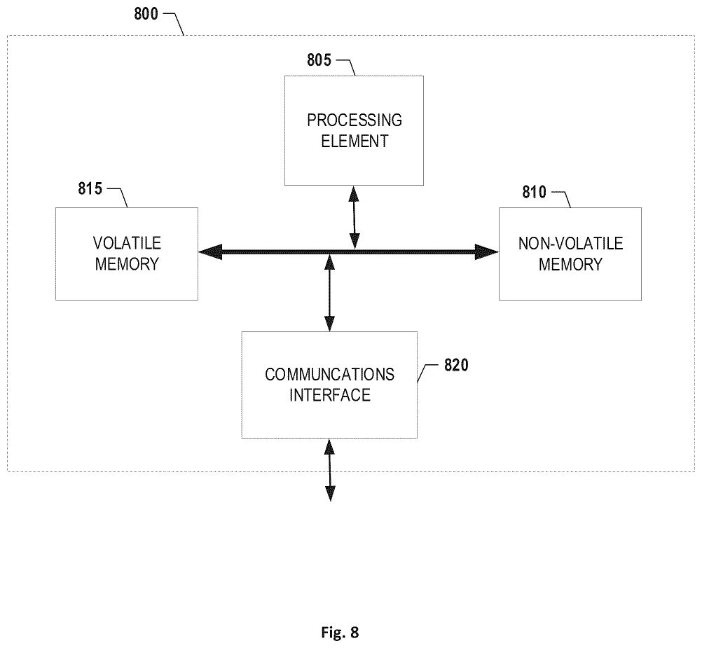

FIG. 8 provides a schematic of an example apparatus 800 that may be used in accordance with various embodiments of the present disclosure. In particular, the apparatus 800 may be configured to perform various example operations described herein to provide for obfuscation, algebraic transformation, structural artifact removal, and/or interconnect structure transformation for security of integrated circuits. In some example embodiments, the apparatus 800 may be embodied by the hardware design process 100.

In general, the terms computing entity, entity, device, and/or similar words used herein interchangeably may refer to, for example, one or more computers, computing entities, desktop computers, mobile phones, tablets, phablets, notebooks, laptops, distributed systems, items/devices, terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably.

Although illustrated as a single computing entity, those of ordinary skill in the field should appreciate that the apparatus 800 shown in FIG. 8 may be embodied as a plurality of computing entities, tools, and/or the like operating collectively to perform one or more processes, methods, and/or steps. As just one non-limiting example, the apparatus 800 may comprise a plurality of individual data tools, each of which may perform specified tasks and/or processes.

Depending on the embodiment, the apparatus 800 may include one or more network and/or communications interfaces 820 for communicating with various computing entities, such as by communicating data, content, information, and/or similar terms used herein interchangeably that can be transmitted, received, operated on, processed, displayed, stored, and/or the like. Thus, in certain embodiments, the apparatus 800 may be configured to receive data from one or more data sources and/or devices, as well as receive data indicative of input, for example, from a device.

The networks used for communicating may include, but are not limited to, any one or a combination of different types of suitable communications networks such as, for example, cable networks, public networks (e.g., the Internet), private networks (e.g., frame-relay networks), wireless networks, cellular networks, telephone networks (e.g., a public switched telephone network), or any other suitable private and/or public networks. Further, the networks may have any suitable communication range associated therewith and may include, for example, global networks (e.g., the Internet), MANs, WANs, LANs, or PANs. In addition, the networks may include any type of medium over which network traffic may be carried including, but not limited to, coaxial cable, twisted-pair wire, optical fiber, a hybrid fiber coaxial (HFC) medium, microwave terrestrial transceivers, radio frequency communication mediums, satellite communication mediums, or any combination thereof, as well as a variety of network devices and computing platforms provided by network providers or other entities.

Accordingly, such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the apparatus 800 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), 5G New Radio (5G NR), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The apparatus 800 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

In addition, in various embodiments, the apparatus 800 includes or is in communication with one or more processing elements 805 (also referred to as processors, processing circuitry, and/or similar terms used herein interchangeably) that communicate with other elements within the apparatus 800 via a bus, for example, or network connection. As will be understood, the processing element 805 may be embodied in several different ways. For example, the processing element 805 may be embodied as one or more complex programmable logic devices (CPLDs), microprocessors, multi-core processors, coprocessing entities, application-specific instruction-set processors (ASIPs), and/or controllers. Further, the processing element 805 may be embodied as one or more other processing devices or circuitry. The term circuitry may refer to an entirely hardware embodiment or a combination of hardware and computer program products. Thus, the processing element 805 may be embodied as integrated circuits, application specific integrated circuits (ASICs), field programmable gate arrays (FPGAs), programmable logic arrays (PLAs), hardware accelerators, other circuitry, and/or the like.

As will therefore be understood, the processing element 805 may be configured for a particular use or configured to execute instructions stored in volatile or non-volatile media or otherwise accessible to the processing element 805. As such, whether configured by hardware, computer program products, or a combination thereof, the processing element 805 may be capable of performing steps or operations according to embodiments of the present disclosure when configured accordingly.

In various embodiments, the apparatus 800 may include or be in communication with non-volatile media (also referred to as non-volatile storage, memory, memory storage, memory circuitry, and/or similar terms used herein interchangeably). For instance, the non-volatile storage or memory may include one or more non-volatile storage or non-volatile memory media 810 such as hard disks, ROM, PROM, EPROM, EEPROM, flash memory, MMCs, SD memory cards, Memory Sticks, CBRAM, PRAM, FeRAM, RRAM, SONOS, racetrack memory, and/or the like. As will be recognized, the non-volatile storage or non-volatile memory media 810 may store files, databases, database instances, database management system entities, images, data, applications, programs, program modules, scripts, source code, object code, byte code, compiled code, interpreted code, machine code, executable instructions, and/or the like. The terms database, database instance, database management system entity, and/or similar terms used herein interchangeably and in a general sense refer to a structured or unstructured collection of information/data that is stored in a computer-readable storage medium.

In particular embodiments, the non-volatile memory media 810 may also be embodied as a data storage device or devices, as a separate database server or servers, or as a combination of data storage devices and separate database servers. Further, in some embodiments, the non-volatile memory media 810 may be embodied as a distributed repository such that some of the stored information/data is stored centrally in a location within the system and other information/data is stored in one or more remote locations. Alternatively, in some embodiments, the distributed repository may be distributed over a plurality of remote storage locations only. As already discussed, various embodiments contemplated herein use data storage in which some or all of the information/data required for various embodiments of the disclosure may be stored.

In various embodiments, the apparatus 800 may further include or be in communication with volatile media (also referred to as volatile storage, memory, memory storage, memory circuitry, and/or similar terms used herein interchangeably). For instance, the volatile storage or memory may also include one or more volatile storage or volatile memory media 815 as described above, such as RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like.

As will be recognized, the volatile storage or volatile memory media 815 may be used to store at least portions of the databases, database instances, database management system entities, data, images, applications, programs, program modules, scripts, source code, object code, byte code, compiled code, interpreted code, machine code, executable instructions, and/or the like being executed by, for example, the processing element 805. Thus, the databases, database instances, database management system entities, data, images, applications, programs, program modules, scripts, source code, object code, byte code, compiled code, interpreted code, machine code, executable instructions, and/or the like may be used to control certain aspects of the operation of the apparatus 800 with the assistance of the processing element 805 and operating system.

As will be appreciated, one or more of the computing entity's components may be located remotely from other computing entity components, such as in a distributed system. Furthermore, one or more of the components may be aggregated, and additional components performing functions described herein may be included in the apparatus 800. Thus, the apparatus 800 can be adapted to accommodate a variety of needs and circumstances.

### CONCLUSION

Many modifications and other embodiments of the disclosures set forth herein will come to mind to one skilled in the art to which these disclosures pertain having the benefit of the teachings presented in the foregoing descriptions and the associated drawings. Therefore, it is to be understood that the disclosures are not to be limited to the specific embodiments disclosed and that modifications and other embodiments are intended to be included within the scope of the appended claims. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. The disclosed embodiments relate primarily to interleaved coupled inductors transformers, one skilled in the art may recognize that such principles may be applied to any transformer device. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

1. A method for netlist obfuscation of a printed circuit board (PCB), comprising:
generating a plurality of connections interconnecting a plurality of components of the PCB using additive manufacturing;
permuting, using a micro electro-mechanical systems (MEMS) device, a first set of connections interconnecting a first component with a second component in the PCB;
integrating the MEMS device into the PCB such that the MEMS device covers a second set of connections from an x-ray probe;
probing the PCB using x-ray simulation; and
iteratively adjusting the permutation of the first set of connections and the integration of the MEMS device using a result of the x-ray simulation to reduce the detectability of the first and second connections based on the result of the x-ray simulation.

2. The method of claim 1, wherein the additive manufacturing comprises three-dimensional printing of the plurality of connections in the PCB.

3. The method of claim 1, further comprising creating a design manufacturing file in response to a result of the x-ray simulation being satisfactory, wherein the design manufacturing file includes instructions on the permutation of the first set of connections and the integration of the MEMS device, and the design manufacturing file configured to be used in netlist obfuscation of another printed circuit board.

4. The method of claim 1, further comprising supplemental obfuscation of the PCB in response to the result of the x-ray simulation not being satisfactory.

5. The method of claim 4, wherein the supplemental obfuscating comprises adding dummy traces and dummy vias to the PCB.

6. The method of claim 4, wherein the supplemental obfuscating comprises rearranging a plurality of surface mount devices in the PCB.

7. A method for netlist obfuscation of a printed circuit board (PCB), comprising:
generating a plurality of connections interconnecting a plurality of components of the PCB using additive manufacturing;
permuting, using a micro electro-mechanical systems (MEMS) device, a set of connections interconnecting a first component with a second component in the PCB; and
integrating the MEMS device into the PCB such that an Integrated Circuit (IC) in the PCB covers the MEMS device from an x-ray probe.

8. The method of claim 7, wherein the x-ray probe when having a power higher than a threshold power is destructive to the IC.

9. The method of claim 8, wherein the x-ray probe, when having a power lower than the threshold power, is incapable of successfully scanning the MEMS device or determining the permutation of the set of connections.

10. The method of claim 9, comprising:
probing the PCB using an x-ray simulation; and
iteratively adjusting the integration of the MEMS device using a result of the x-ray simulation to reduce the detectability of the set of connections based on the result of the x-ray simulation.

11. A method for obfuscating connections between a first Integrated Circuit (IC) and a second IC of a printed circuit board (PCB), comprising:
inputting a PCB design file determining countermeasures for obfuscating the connections between the first IC and second IC;
performing an X-ray countermeasure simulation to determine a level of obfuscation of the connections between the first and the second IC;
receiving a set of selections for countermeasure settings;
generating X-ray projections from collection types and geometries commensurate with the received set of selections for countermeasure settings;
extracting information on the connections between the first and second ICs by reconstructing X-ray data; and
determining whether the countermeasures are sufficient for obfuscation.

12. The method of claim 11, wherein the set of selections for countermeasure settings comprises a level of difficulty of reverse engineering of the PCB design, a specific connection of the connections between the first and second ICs for high priority obfuscation, an upper limit of cost or overhead for obfuscation, a desired cost or time for reverse engineering of the connections, or an X-ray tool specification.

13. The method of claim 12 comprising converting the PCB design file to a manufacturing file when the countermeasures are sufficient for obfuscation.

14. The method of claim 12 comprising, when the countermeasures are sufficient for obfuscation, selecting a set of the connections between the first IC and the second IC that are visible to the X-ray.

15. The method of claim 14 comprising reconfiguring the PCB design file to obfuscate the set of the connections that are visible to the X-ray.

16. The method of claim 15, wherein the reconfiguring the PCB design file comprises rearranging a surface-mount device (SMD) to absorb X-ray energy.

17. The method of claim 15, wherein the reconfiguring the PCB design file comprises adding dummy traces to the connections between the first IC and the second IC.

18. The method of claim 15, wherein the reconfiguring of the PCB design file comprises permuting, using a micro electro-mechanical systems (MEMS) device, the connections between the first IC and the second IC.

19. The method of claim 18, wherein the MEMS device obfuscates the connections between the first IC and the second IC.

20. The method of claim 14 comprising iteratively repeating, inputting the PCB design file, performing the X-ray countermeasure simulation to determine the level of obfuscation of the connections between the first and the second IC, receiving the set of selections for countermeasure settings, generating X-ray projections from collection types and geometries commensurate with the received set of selections for countermeasure settings, extracting information on the connections between the first and second ICs by reconstructing X-ray data, and determining whether countermeasures are sufficient for obfuscation, until the countermeasures are sufficient for obfuscation.
